(19) United States
(12) Patent Application Publication
(10) Pub. No.: US 2022/0413554 A1
(43) Pub. Date: Dec. 29, 2022

(54) Information Terminal Device

(71) Applicant: KABUSIKIGAISYA DIGIMED, Wakayama (JP)

(72) Inventor: Kaisyou Hoshibata, Wakayama (JP)

(21) Appl. No.: 17/641,783

(22) PCT Filed: May 12, 2020
(86) PCT No.: PCT/JP2020/018914

§ 371 Date: Mar. 9, 2022

(30) Foreign Application Priority Data
Oct. 15, 2019 (JP) 2019-188410

(51) Int. Cl. G06F 1/16

(52) U.S. Cl. CPC G06F 1/1652; G06F 1/163; G06F 1/1616

(57) ABSTRACT

An information terminal device according to the present invention is configured to be compact and realizes high-level functionality and/or multi-functionality by drawing out a film-like input/output portion from a casing when used, in a wristwatch type information device or a mobile information terminal device such as a game machine, for example. In addition, a support member supports a back surface of a free end portion side of the input/output portion, the support member is sandwiched between a guide member and a front frame of a casing, and the guide member enables the support member to move into/out from the casing, and supports the back surface of a base end portion side of the drawn-out input/output portion. Accordingly, a support structure that enables reliably performing input/output operations on the film-like input/output portion can be realized. Also, an angle adjustment mechanism is provided between the support member and the casing.

### TECHNICAL FIELD

The present invention relates to an information terminal device, and particularly to an information terminal device that is favorably implemented in wristwatches.

### BACKGROUND ART

Due to advancements in semiconductor technology, wristwatch sized devices can be equipped with various functions. An example of this is a device that can switch from displaying the time as a watch to being used as a pedometer, and may have various functions with which biological information such as heart rate, blood pressure, and blood oxygen levels can be acquired. However, information that is currently acquired in such a way is difficult to manage, that is to say that the information is merely acquired and difficult to use, and is actually transferred to a smartphone to be used.

Also, as another example, there are also devices that are wristwatch sized and function as wearable terminals. For example, there are devices that include functions such as giving notifications when an email is received, and displaying small portions of email at a time. However, the capabilities of such devices are limited due to the screen, or in other words due to limitations of the size of the dial face. For example, it is difficult to read long emails and perform advanced display of information such as web browsing on such screens, and it is also difficult to perform input operations such as touch panel operations on such display screens.

Therefore, in Patent Document 1, a wristwatch having an information terminal function is proposed in which the screen is folded into two when not used, and the size of the display screen can be roughly doubled by opening the folded screen when used. However, there is a problem in that, because the screen is foldable, in Patent Document 1, a hinge is present between two screens, and the screen continuity is degraded.

Therefore, the inventors of the present invention have proposed Patent Document 2 in advance. Patent Document 2 discloses a wristwatch type information terminal device in which the free end side of an input/output portion made of film is exposed in a dial face portion of a main body, the base end side is housed in the main body in a wound state, and the area of the input/output portion is enlarged by drawing out and expanding the housed portion.

### CITATION LIST

### Patent Document

Patent Document 1: JP 2000-214277A
Patent Document 2: JP 6564923B

### DISCLOSURE OF INVENTION

Patent Document 2 discloses a wristwatch type information terminal device that can realize high-level functionality and/or multi-functionality while maintaining screen continuity. However, in Patent Document 2, there remains room for improvement with respect to a support structure of a film-like input/output portion, specifically the drawn out portion. For example, in Patent Document 2, there is room for improvement regarding responsiveness to touch operations.

An object of the present invention is to provide an information terminal device that can realize high-level functionality and/or multi-functionality with a compact configuration by drawing out a film-like input/output portion, in which the support structure of the input/output portion is improved.

In order to realize the objective described above, an information terminal device according to the present invention is configured to be compact by drawing out a film-like input/output portion from a casing when used, in a wristwatch type information terminal device or a mobile information terminal device such as a game machine, and in order to realize high-level functionality and/or multi-functionality, a support member supports a back surface of a free end portion side of the input/output portion, and is sandwiched between a guide member and a front frame of a casing so as to be able to move into/out from the casing.

Thus, by supporting the back surface of the base end portion side of the drawn out input/output portion, it is possible to realize a support structure that enables reliably performing input/output operations on the film-like input/output portion.

### BRIEF DESCRIPTION OF DRAWINGS

FIG. 1 is a perspective view of a wristwatch type information terminal device according to one embodiment of the present invention, and shows a state when used as an information terminal device.

FIG. 2 is a perspective view of the information terminal device shown in FIG. 1, and shows a state when used as a wristwatch.

FIG. 3 is a perspective view at the time of changing from FIG. 2 to FIG. 1, or from FIG. 1 to FIG. 2.

FIG. 4 is an exploded perspective view of the information terminal device shown in FIGS. 1 to 3.

FIG. 5 is an exploded perspective view showing an example of a configuration of an angle adjustment mechanism.

FIG. 6 is a perspective view of the wristwatch type information terminal device according to another embodiment of the present invention, and shows a state when used as an information terminal device.

FIG. 7 is a perspective view of the information terminal device shown in FIG. 6, and shows a state when used as a wristwatch.

FIG. 8 is an exploded perspective view of the information terminal device shown in FIGS. 6 and 7.

### DESCRIPTION OF THE INVENTION

### First Embodiment

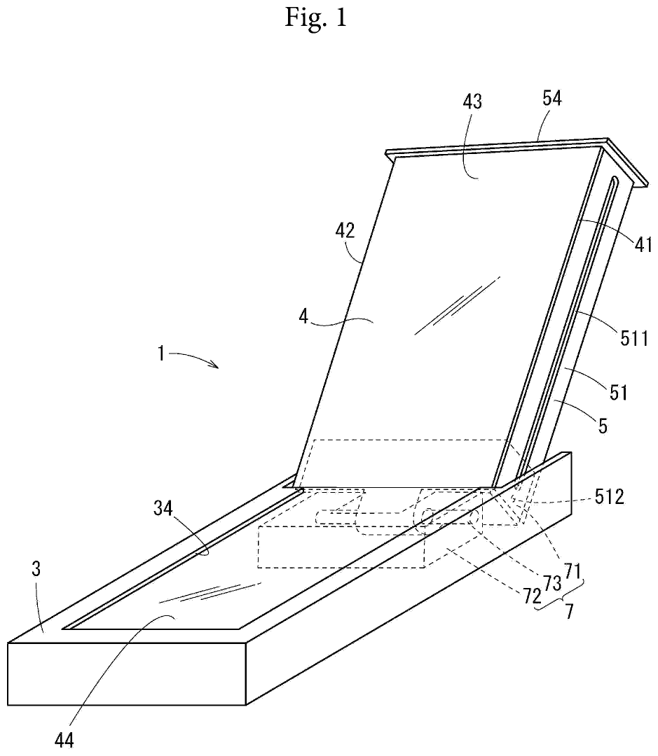

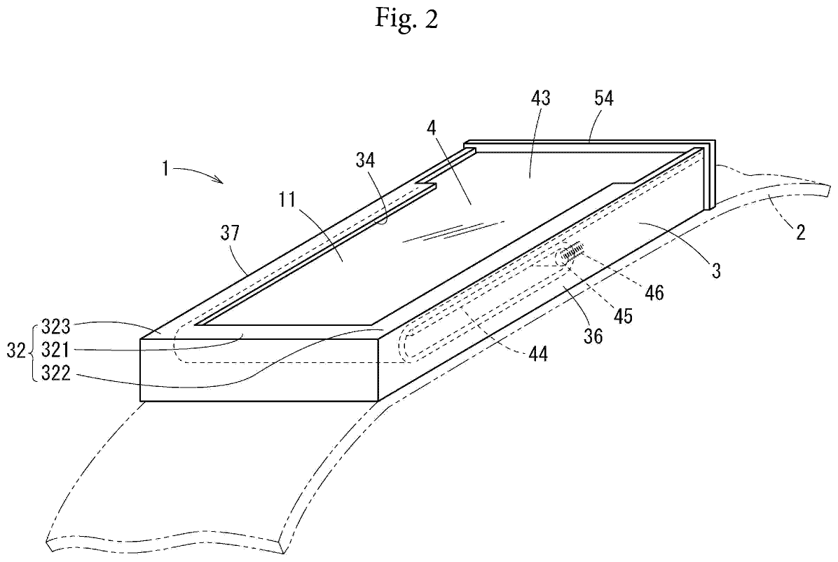

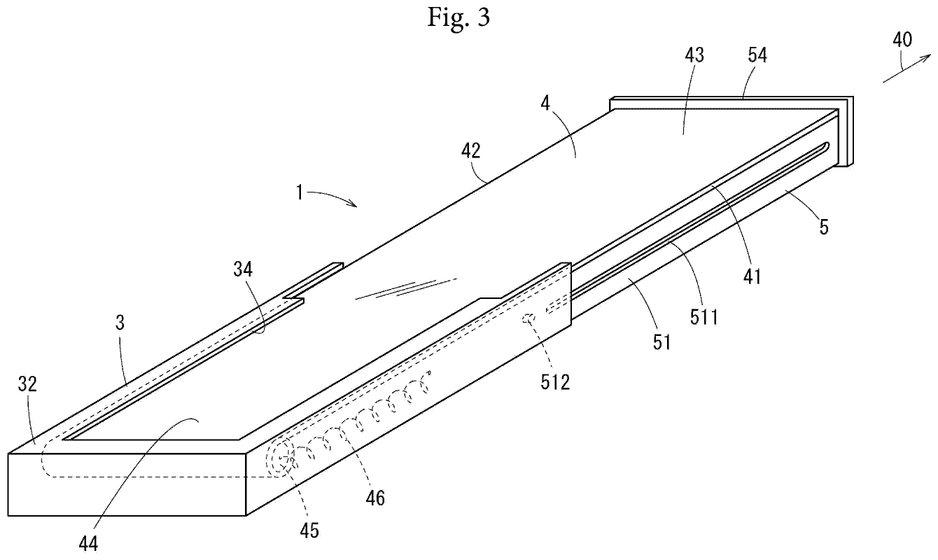

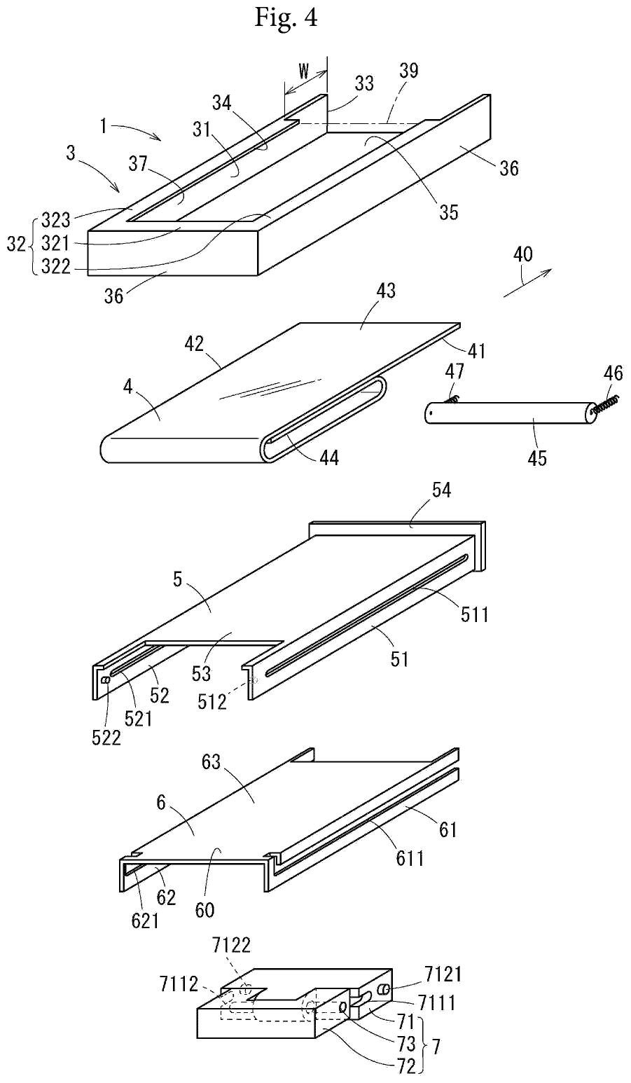

FIGS. 1 to 3 are perspective views of a wristwatch type information terminal device 1 according to one embodiment of the present invention. FIG. 1 shows a state when used as an information terminal device, FIG. 2 shows a state when used as a wristwatch, and FIG. 3 shows changing states between FIG. 1 and FIG. 2. FIG. 4 is an exploded perspective view of the information terminal device 1. A wristband 2 for a wristwatch is shown in FIG. 2 using imaginary lines, which are omitted from the other drawings to simplify the drawings. A wristwatch type information terminal device 1 is illustrated in FIGS. 1 to 4, but the present invention can be implemented in mobile information terminal devices such as a game machine, a mobile phone, a tablet terminal, a personal computer, and the like.

The information terminal device 1 of the present embodiment displays the time in a dial face portion 11, when used as a wristwatch. In addition thereto, the information terminal device 1 may display seconds, the date, day of the week, year, and the like, as appropriate, and may also display the number of steps, blood pressure and heart rate measured by a biosensor (not shown), or the like in response to the user changing modes. Basically, switching between such modes and the like is performed through a touch sensor or the like provided on the dial face portion 11 of the information terminal device 1, but may also be appropriately performed with the use of a crown, a button, or the like provided on a side portion or the like of a casing 3.

As will be described in detail using FIG. 4, this information terminal device 1 is overall configured to include the casing 3, an input/output portion 4, a support member 5, a guide member 6, and an angle adjustment mechanism 7. The input/output portion 4 is formed as a film that has a pair of sides 41 and 42 that are parallel to each other, and realizes display and/or input operations as the information terminal device. FIGS. 1 and 3 show the film-like input/output portion 4 in an extended state, and FIGS. 2 and 4 show the input/output portion 4 in a wound state. In the information terminal device 1 of the present embodiment, the input/output portion 4 has a band shape that includes the pair of sides 41 and 42 that are parallel to each other, and is used divided in substantially half. A free end portion 43 side that is one of the substantial halves is constantly exposed to the outside when used as the wristwatch, and a base end portion 44 side that is the other substantial half is stored in a space 31 in the casing 3 when used as the wristwatch and is drawn out when used as the information terminal device. In the example shown in FIG. 4, the base end portion 44 side of the input/output portion 4 is stored rolled in an oblong shape in a longitudinal cross-section thereof, but may be stored wound in a normal spiral shape.

The input/output portion 4 is formed by stacking a touch panel on an electronic paper or an organic EL film display that perform display, thus enabling display output and touch input. Such electronic papers or organic FT film displays are thin and flexible, and are favorable as the film-like input/output portion 4 that is housed wound or bent in the casing 3 and forms a continuous screen when drawn out. Also, as one example of an organic EL film display, an organic EL film display with a resin substrate is favorable as it is thin and flexible. While, as described above, the input/output portion 4 has the pair of sides 41 and 42 that are parallel to each other so as to allow the input/output portion 4 to be drawn out in a drawing out direction 40, the input/output portion 4 is not necessarily limited to being rectangular, and, in particular, the free end portion 43 side, which is exposed when used a wristwatch, may be formed in a shape such as an arc shape according to a design.

The casing 3 is formed such that an opening is formed in the front surface of a cube (box), that is, the surface serving as the front surface when used a wrist watch, while leaving a front frame 32 remaining, and one side portion 33 (in the examples shown in FIGS. 1 to 4, the upper surface when used as the wristwatch) is open. The input/output portion 4 is exposed from an opening portion 34 of this front frame 32. Also, as described below, the input/output portion 4, the support member 5, the guiding member 6, and the angle adjustment mechanism 7 are housed in this casing 3. The support member 5 and the guiding member 6 are stacked on one another.

The front frame 32 is overall U-shaped, and has the function of pressing down the peripheral edge portion of the film-like input/output portion 4. The front frame 32 is configured to include a first frame portion 321 that covers the side of the support member 5 that is opposite to the drawing out side, and second and third frame portions 322 and 323 that respectively cover two side portions (41 and 42) of the input/output portion 4. The second and third frame portions 322 and 323 are not formed to cover the entire length up to the one side portion 33, but are instead shortened (cut out) by a predetermined length W as described below.

The support member 5 is able to move into/out from the casing 3 in the direction of the pair of sides 41 and 42 of the input/output portion 4, that is, in the drawing out direction 40, and is attached to the free end portion 43 side of the input/output portion 4 to planarly support the free end portion 43 side from the back surface side thereof, for example. Accordingly, touch operations and the like can be performed on the input/output portion 4 without hindrance, and the input/output portion 4 can be drawn out from the casing 3 in one piece with the support member 5. In the present embodiment, the support member 5 is formed by folding two widthwise end portions 51 and 52 of an elongated plate-shaped body so that the cross-section in the short direction thereof is substantially U-shaped. A flat plate portion 53 at the center of the U shape supports the free end portion 43 side of the input/output portion 4, and one end portion of the flat plate portion 53 (end portion on the drawing out side) is provided with a projection 54 on which the user hooks his/her finger to draw out the support member.

The guide member 6 is disposed on the back surface side of the front frame 32 of the casing 3 so that when the support member 5 is in a storage state, the support member 5 is located on the front surface thereof, that is, the support member 5 is stacked thereon, and supports the base end side 44 of the drawn out film-like input/output portion 4 from the back surface thereof so as to be planar and so as to enable touch operations free of hindrance. The input/output portion 4 is housed wound or bent in the pair of sides 41 and 42 direction (40), in the space 31 between this guide member 6 and a bottom surface 35 of the casing 3. The input/output portion 4 is drawn out from or wound back into the space 31 via a gap formed between an end portion 36 of the casing 3 on the side of the support member 5 opposite to the drawing out side and an end portion 60 of the guide member 6. The guide member 6 is formed by folding two widthwise end portions 61 and 62 of an elongated plate-shaped body so that the cross-section in the short direction thereof is substantially U-shaped, and is fitted into the support member 5 and fixed to the bottom surface 35 of the casing 3 so that the support member 5 can be drawn out.

Note that, in the present embodiment, the support member 5 and the guide member 6, which are stacked on one another, are formed so that the cross sections in the short directions thereof are substantially U-shaped, but the cross-sections may at least be L-shaped. In other words, a configuration may be employed where the two end portions 51 and 52 of the support member 5 are sandwiched between side walls 36 and 37 of the casing 3 and the two end portions 61 and 62 of the guide member 6, and the flat plate portion 53 of the support member 5 is sandwiched between the rear side of the front frame 32 and a flat plate portion 63 of the guide member 6 so as to enable smooth sliding of the support member 5 in the drawing out direction 40.

By employing such a configuration, in a mobile information terminal device, the free end portion 43 side is exposed from the opening portion 34 when the input/output portion 4 is in a storage state such as that in FIG. 2, and input/output operations can be made with the exposed portion alone. On the other hand, as shown in FIGS. 3 to 1, the input/output portion 4 is drawn out in one piece with the support member 5 when the support member 5 is drawn out in the drawing out direction 40, and the base end portion 44 side is drawn out from the space 31 via the gap and faces the opening portion 34. In doing so, the input/output portion 4 is supported by the guide member 6 from the back surface side thereof, the peripheral edge portion of the front surface side is pressed down by the front frame 32, and the entire surface of the input/output portion 4 can be used to make input and output operations. Accordingly, the information terminal device 1 can realize high-level functionality and/or multi-functionality with a compact configuration by drawing out the input/output portion 4. Also, even when the film-like input/output portion 4 is drawn out, the free end portion 43 side of the input/output portion 4 is supported (backed) by the support member 5, and the base end portion 44 side is supported (backed) by the guide member 6, and thus improvements in the support structure can be realized.

Also, although the wristwatch type information terminal is small and compact, the amount of display and/or input operations is limited with only the area of the dial face, whereas by enlarging the area of the input/output portion by drawing out the input/output portion 4, as appropriate, as in the information terminal device 1 according to the present embodiment, the functionality as an information terminal device can be improved, and the device is favorable.

It should be noted that the information terminal device 1 of the present embodiment is configured as follows such that the free end portion 43 side of the film-like input/output portion 4 and the support member 5 on which the free end portion side is mounted can be drawn out from one side (the one side portion 33) of the casing 3 and supported with an adjustable angle. Specifically, first, in the support member 5 and the guide member 6 that each have a U-shaped cross section and are stacked on one another, the folded portions (two end portions 61 and 62) of the guide member 6 are respectively provided with first elongated holes 611 and 621 for guiding. In correspondence therewith, in the vicinity of the end portions of the bent portions (two end portions 51 and 52) of the support member 5 on the opposite side to the drawing out side, first guide pins 512 and 522 are provided protruding inward and are respectively fitted into the first elongated holes 611 and 621. Thus, the input/output portion 4 and the support member 5 can be drawn out.

Next the guide member 6 is formed shortened to extend to a position a predetermined length inward of the one side portion 33 on the drawing out side of the casing 3. Accordingly, the angle adjustment mechanism 7 is provided in the thus secured space on the exit side of the casing 3. The angle adjustment mechanism 7 is configured to include an angular displacement member 71 that is continuous with the guide member 6, and a fixed member 72 that is fitted into the support member 6 and fixed to the bottom surface 35 of the casing 3 to pivotably support the angular displacement member 71 so as to enable angle adjustment. Also to be noted, in order to support and guide the U-shaped support member 5 from the inward side thereof, the angular displacement member 71 includes pin holes 7111 and 7112 that are respectively in communication with the first elongated holes 611 and 621 of the guide member 6, and receive the first guide pins 512 and 522 when the support member 5 is drawn out.

Accordingly, as the support member 5 is drawn out in the drawing out direction 40, the first guide pins 512 and 522 move from the first elongated holes 611 and 621 of the guide member 6 into the corresponding pin holes 7111 and 7112 of the angular displacement member 71. That is, the support member 5 is transferred from the guide member 6 to the angular displacement member 71 of the angle adjustment mechanism 7. Thus, it is possible to realize an input/output portion whose angle can be adjusted once drawn out.

In the information terminal device 1 of the present embodiment, the drawn out support member 5 and the casing 3, that is, the portion spanning from the free end portion 43 side to the base end portion 44 side of the film-like input/output portion 4, not only extend on straight lines as shown in FIG. 3, but are also connected at an angle as shown in FIG. 1 as a result of providing the angle adjustment mechanism 7. Thus, in a wristwatch type information terminal device, for example, the free end portion 43 side of the drawn out input/output portion 4 faces upward, which improves visibility, or in an information terminal device used as a mobile phone, the free end portion 43 side approaches an ear, and the base end portion 44 side approaches a mouth, which makes talking easier.

Also, in the information terminal device 1 of the present embodiment, second elongated holes 511 and 521 that extend in the drawing out direction 40 of the support member 5 are provided in the bent portions (two end portions 51 and 52) of the support member 5, respectively. In correspondence therewith, second guide pins 7121 and 7122 that are respectively fitted into the second elongated holes 511 and 521 are provided outward of the pin holes 7111 and 7112 of the angular displacement member 71. Accordingly, the guide member 5 is guided by the two elongated holes 611, 621; 511, 521 and the two guide pins 512, 522; 7121, 7122 that the two elongated holes correspondingly receive, the elongated holes and the guide pins being provided in the guide member 6 and the angular displacement member 71, and thus rattling in the slide operations of the support member 5 and the input/output portion 4 can be suppressed. Also, in the case where only the first guide pins 512 and 522 are employed, if the first guide pins 512 and 522 are columnar in shape, the support member 5 may be angularly displaced from the angular displacement member 71 with the first guide pins 512 and 522 acting as rotation shafts. In view of this, such a problem can be prevented by combining the first guide pins 512 and 522 with the second guide pins 7121 and 7122. Note that, in the case where only the first guide pins 512 and 522 are employed, rotation such as that described above can be prevented by making the first guide pins 512 and 522 square columns or plate shaped.

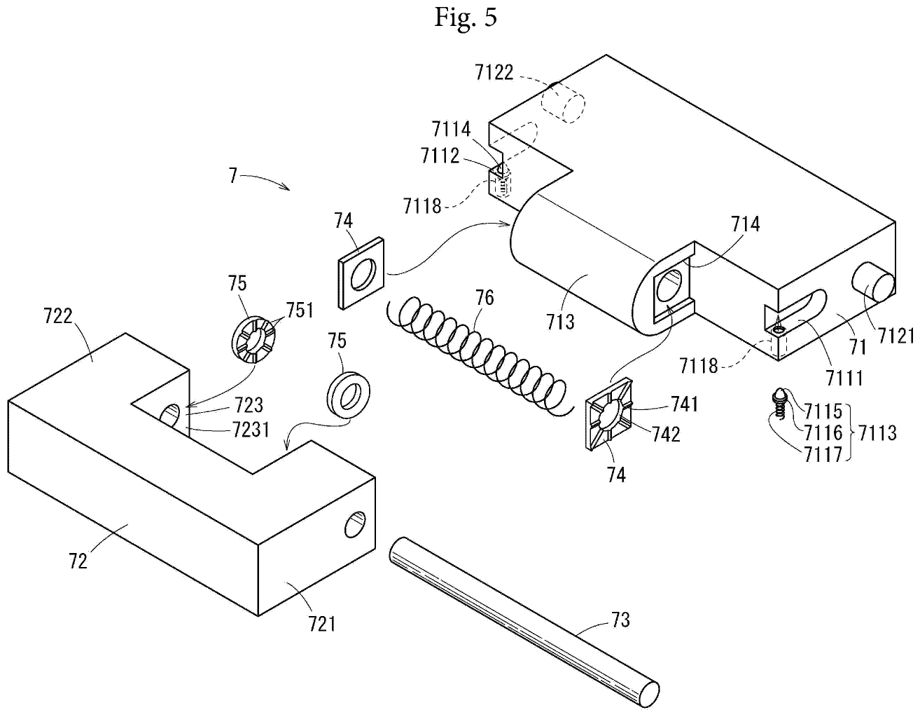

FIG. 5 is an exploded perspective view showing an example of a configuration of the angle adjustment mechanism 7. In the example shown in FIG. 5, the fixed member 72 is formed to be overall concave and the angular displacement member 71 is formed to be overall convex as seen from the front, and angular displacement therebetween is realized by fitting a recess portion 723 and a protrusion portion 713 to each other and a pin 73 that pivotably supports the fixed member and the angular displacement member. The protrusion portion 713 has a mountain shape in a cross section perpendicular to the axis of the pin 73 so as to not interfere with the bottom plate 35 or the input/output portion 4 at the time of angular displacement. Note that a configuration is possible where the fixed member 72 is convex and the angular displacement member 71 is concave, in which case two side portions 721 and 722 of the recess portion 723 would have a mountain shape in a cross section perpendicular to the axis.

A rectangular storage hole 714 is provided on each side of the protrusion portion 713. A friction plate 74 is stored in each of the storage holes 714, and protrusions/recessions 741 are alternatingly provided in the circumferential direction of each friction plate 74. The friction plate 74 includes a hole 742 at the center thereof into which the pin 73 is to be inserted, the back surface side faces the bottom surface of the storage hole 714, and the front surface side is exposed from the storage hole 714 and faces an opposing surface 7231 of the recess portion 723. The friction plate 74 is biased toward the opposing surface 7231 from the back surface side by a coil spring 76 that is wound around the pin 73.

On the other hand, in correspondence therewith, friction plates 75 are also respectively fixed to the opposing surfaces 7231 of the recess portion 723. The friction plates 75 each include protrusions/recessions 751 similar to those of the friction plates 74. Accordingly, an angle is held for each interval between the protrusions/recessions 741 and 751. Thus, in a state where the coil spring 76 is stored inside the protrusion portion 713 and the friction plates 74 are respectively fitted into the storage holes 714, the angle adjustment mechanism 7 can be completed by fitting the protrusion portion 713 into the recess portion 723 to which the friction plates 75 have been attached and inserting the pin 73. Then, in a state where the support member 5 and the input/output portion 4 are completely drawn out as shown in FIG. 3, by angularly displacing the protrusions/recessions 741 against the elastic force of the coil spring 76 by a force with which they move over the protrusions/recessions 751, the angle adjustment mechanism 7 is angularly displaced and the angle adjustment mechanism 7 holds that angle while the protrusions/recessions 741 and 751 are engaged with each other. In this way, the information terminal device 1 can be used folded as shown in FIG. 1. Note that the frictions plates 74 and 75 are not limited to the combination of the protrusions/recessions 741 and 751, and other configurations such as rubber plates with a high frictional coefficient, plates with hooks and plates with fibers for catching the hooks, and the like may be employed. Also, the spring that biases the friction plates 74 is not limited to the coil spring 76 wound around the pin 73, and a configuration such as a plate spring provided on the bottom portion of each storage hole 714 may be employed.

Also, it should be noted that, the angular displacement member 71 of the angle adjustment mechanism 7 includes locking members 7113 and 7114 that, on an entrance side of the pin holes 7111 and 7112, retract from the entrance under a pressing force of the first guide pins 512 and 522 upon the first guide pins 512 and 522 entering the pin holes, and block off the entrances after entry. In the example shown in FIG. 5, the locking members 7113 and 7114 are configured to include cone shaped projections 7115 that respectively protrude into the pin holes 7111 and 7112, flanges 7116 that function as retainers at the bottom surface of the corresponding projection, and coil springs 7117 that respectively elastically bias the projections 7115 in a protruding direction from the rear side thereof. In correspondence therewith, the angular displacement member 71 is provided with storage holes 7118 for the locking members 7113 and 7114.

Accordingly, when the first guide pins 512 and 522 are respectively fitted into the pin holes 7111 and 7112, the locking members 7113 and 7114 act as retainers (prevent retraction), and thus the first guide pins 512 and 522 can stably transition from the first elongated holes 611 and 621 to the pin holes 7111 and 7112. Thus, even if the base end side 44 of the input/output portion 4 is pulled by springs 46 and 47 or the like and subjected to tension, a situation such as the drawn out input/output portion 4 and the support member 5 being undesirably drawn back can be prevented, and there is no need to separately provide a locking means so as to keep the drawn out input/output portion 4 and the support member from being drawn back. Also, when the support member 5 is pushed back in with a force that pushes down the locking members 7113 and 7114, the locking is released, and the support member 5 and the input/output portion 4 can be stored in the direction opposite to the drawing out direction 40.

Here, in the example shown in FIG. 4, the base end portion 44 side of the input/output portion is stored rolled in an oblong shape in a longitudinal cross-section thereof, as described above. Specifically, the space 31 formed by the flat plate portion 63 of the guide member 6 and the bottom plate 35 of the casing 3 has a shallow box shape, and the base end portion 44 side of the input/output portion 4 is stored rolled in an oblong shape in the space 31. Thus, the base end portion 44 is fixed to the rear surface of the flat plate portion 63, and is appropriately connected to a circuit that realizes the function of the information terminal device 1 by using a wiring substrate or the like. The input/output portion 4 is folded back from the base end portion 44 around a roller 45 located circumferentially inward thereof such that the input/output portion extends toward a gap formed between the end portion 36 of the casing 3 on the side opposite to the drawing out side of the support member 5 and the end portion 60 of the guide member 6, and thus the cross section of the input/output portion 4 thereof takes an oblong shape. Furthermore, the roller 45 is biased by the springs 46 and 47 in a direction in which the input/output portion 4 is drawn back. In this way, the base end portion 44 side of the elongated input/output portion 4 can be stored in a folded back state.

In order to draw out the film-like input/output portion 4 through a gap formed between the end portion 36 of the casing 3 on the opposite side to the drawing out side of the support member 5 and the end portion 60 of the guide member 6, the front frame 32 that presses down the peripheral edge portion of the input/output portion 4 has an overall U shape, and the first frame portion 321 covers the gap while the second and third frame portions 322 and 323 respectively cover two side portions (41 and 42) of the input/output portion 4. In doing so, the input/output portion 4 can be one continuous screen from the free end portion 43 side, which is exposed before the input/output portion is drawn out, to the base end portion 44 side that appears when drawn out.

Also, the second and third frame portions 322 and 323 are not formed to cover the entire length up to the one side portion 33, but are instead shortened (cut out) by a later-described predetermined length W from the one side portion 33, and an extension line 39 of these cut out portions is the folding line of the angularly displaced input/output portion 4 made continuous by the angular displacement member 71 and the fixed member 72. Accordingly, even if the drawn out support member 5 and input/output portion 4 are angularly displaced inward, a folding line does not appear, and the continuous screen can bent along a smooth curve.

In the aforementioned example, the casing 3, the support member 5, and the guide member 6 extend in straight lines as viewed laterally, but the peripheral edge of the film-like input/output portion 4 is pressed by the front frame 32, and thus may be formed in an arc shape, that is, a round shape, that matches the wrist of a user. Also, by making the support member 5 stepped, the drawing out length of the input/output portion 4 can be increased relative to the length of the casing 3.

Furthermore, the angle adjustment mechanism 7 may be omitted if fine angle adjustment and folding at large angles are not required, and a configuration is possible in which only the angle displacement member 71 to which the support member 5 is transferred is provided fixed to the bottom surface 35, the pin holes 7111 and 7112 have arc shapes, and the first guide pins 512 and 522 that are fitted thereinto have plate shapes. Accordingly, the support member 5 and the free end portion 43 side of the input/output portion 4 can be raised and fixed at an angle of 30°, for example. Members that can be unlocked in response to a button being operated may be used as the locking members 7113 and 7114 that retain the first guide pins 512 and 522.

### Second Embodiment

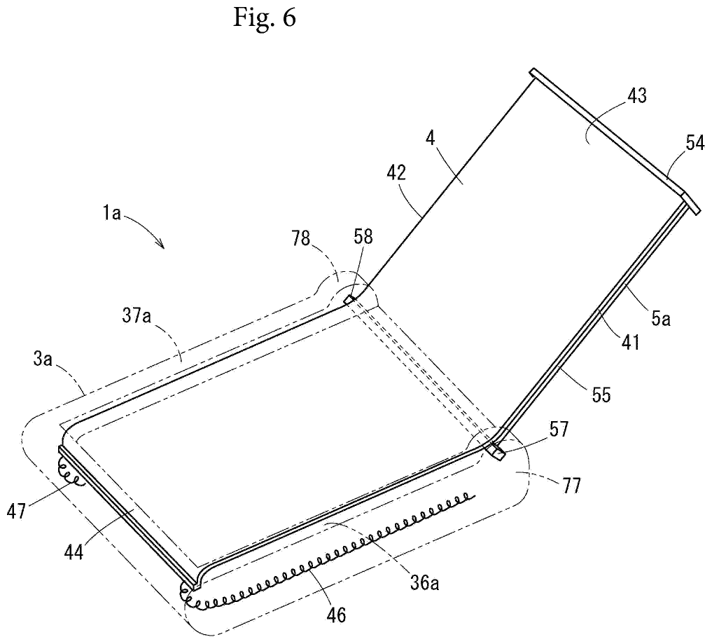

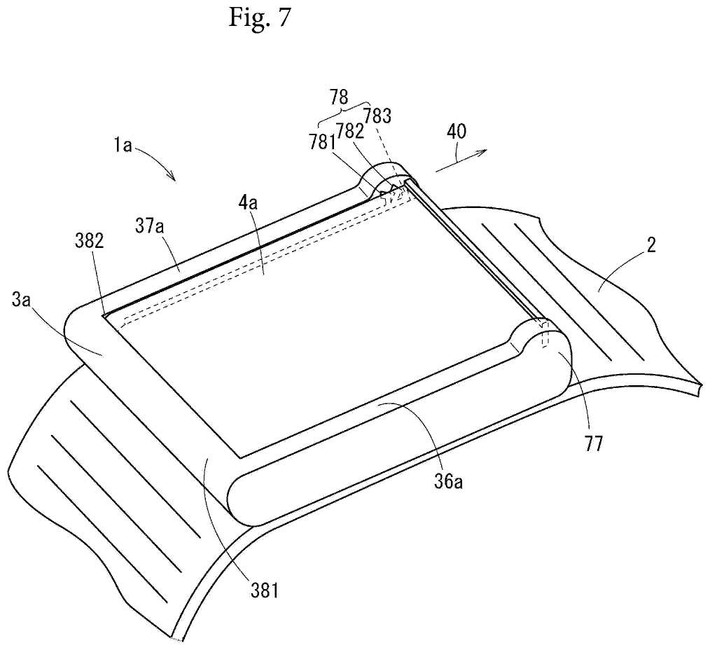

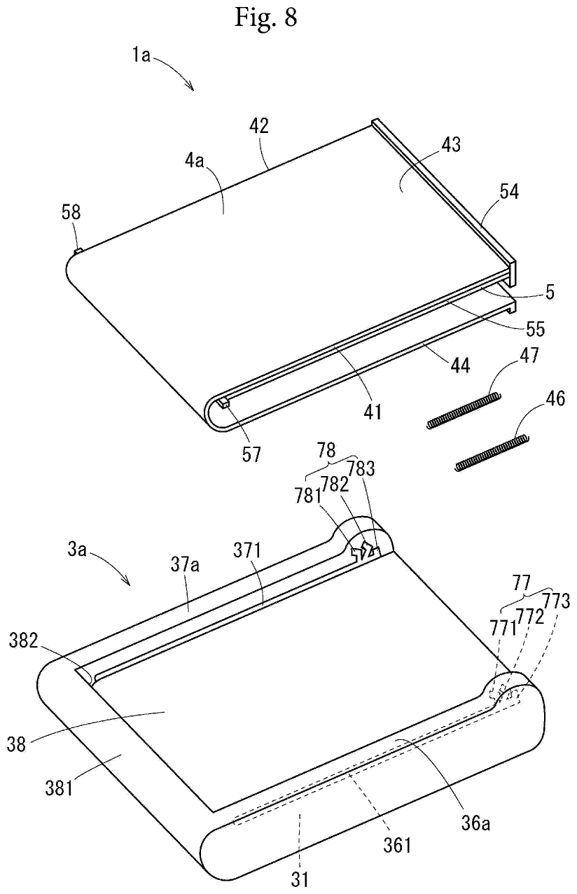

FIGS. 6 and 7 are perspective views of a wristwatch type information terminal device 1a according to another embodiment of the present invention. FIG. 6 shows a state when used as an information terminal device, and FIG. 7 shows a state when used as a wristwatch. FIG. 8 is an exploded perspective view of the information terminal device 1a. The information terminal device 1a is similar to the aforementioned information terminal device, and the portions corresponding to those in the information terminal device 1 are given the same reference numerals, and the description thereof will be omitted.

It should be noted that, in this information terminal device 1a, a support member 5a backing the free end portion 43 side of an input/output portion 4a does not have a complicated U-shaped cross-section such as in the case of the aforementioned support member 5, and is simply plate-shaped. However, the base end side is provided with pins 57 and 58 that respectively extend from the pair of sides 41 and 42 in opposite directions away from each other.

On the other hand, a casing 3a includes a support surface 38 that supports the input/output portion 4a from the back surface side, and the base end portion 44 side, which is a portion of the input/output portion 4a, is housed wound or bent in the longitudinal direction thereof in the internal space 31 inside the casing. In this casing 3a, the base end portion 44 side of the input/output portion 4a is drawn out from the aforementioned internal space 31 via a gap (slit) 382 formed in a lower portion 381, and the base end portion 44 side is placed (expanded) on the support surface 38. Two sides of the support surface 38 of the casing 3a are respectively provided with ridges (edges) 36a and 37a that respectively include guide grooves 361 and 371, which are parallel with the support surface 38. By fitting the pins 57 and 58 into the guide grooves 361 and 371, respectively, the support member 5a and the free end portion 43 side of the input/output portion 4a backed thereby can slide on the support surface 38, that is, move into/out of the casing 3a. These pins 57 and 58 and the guide grooves 361 and 371 constitute a guide means.

Also the casing 3a includes a pair of angle adjustment mechanisms 77 and 78. In the example shown in FIG. 8, the angle adjustment mechanisms 77 and 78 are formed by slots 771, 772, 773 and 781, 782, 783, which are in communication with the corresponding guide grooves 361 and 371 and extend at a plurality (three in FIG. 8) of angular positions. Accordingly, the pins 57 and 58 are prismatic or plate shaped. Thus, when the support member 5a and the input/output portion 4a are drawn out in the drawing out direction 40, the pins slide without rotating in the guide grooves 361 and 371, and continue on to be fitted into and fixed in any one of the rectangular slots 771, 772, 773; 781, 782, 783 that are in communication with the guide grooves 361 and 371. In the example shown in FIG. 8, a step portion is formed on the exit side of each of the slots 771, 772, 773; 781, 782, 783, and the prismatic or plate shaped pins 57 and 58 are retained therein once they enter and catch on the corresponding step portion. Accordingly, even if the input/output portion 4a is biased in the drawing back direction by the springs 46 and 47, the input/output portion 4a and the member 5a can be held in the drawn out state. It is sufficient to operate the support member 5a so as to move the pins 57 and 58 over the step portions when storing the input/output portion 4a.

With such a configuration, by fitting the pins 57 and 58 into any one pair of the slots 771, 772, 773; 781, 782, 783, the user can adjust the angle of the free end portion 43 side of the input/output portion 4a. Also, as a result of supporting the portion of the input/output portion 4a that is constantly exposed (this is referred to as the free end portion 43 side) by attaching it to the plate shaped support member 5a or the like, and further drawing out the support member from one side portions of the casing 3a, the input/output portion 4a can be exposed continuous from the free end portion 43 side to the base end portion 44 side of the input/output portion. At this time, the back surface of the free end portion 43 side of the input/output portion 4a is supported by the support member 5a, and the drawn out base end portion 44 side is supported from the back surface side by the support surface 38, which is the front surface of the casing 3a, and thus touch operations and the like can be performed on the entire input/output portion 4a without hindrance with a very simple configuration.

Furthermore, in a state where the support member 5a is drawn out, the region spanning from the free end portion 43 side of the input/output portion 4a to the base end portion 44 side extends in a substantially planar manner, that is, extends in a substantially straight line, and thus the angle adjustment mechanisms 77 and 78 can be provided to improve visibility or facilitate operations. If it is sufficient to adjust to a single angle such as the case as with a conventional flip phone, as they are called in Japan, the angle adjustment mechanisms 77 and 78 may simply be constituted by slots 771 and 781, for example.

The information terminal device of the present invention is a mobile information terminal device including: an input/output portion that is film-like and includes a pair of sides that are parallel to each other, and realizes display and/or input operations as the information terminal device; a casing that includes an opening portion that exposes the input/output portion, in a front frame of a front surface thereof; a support member configured to move into/out from the casing in a direction along the pair of sides of the input/output portion, and configured to be drawn out from the casing in one piece with the input/output portion by supporting a free end portion side, with respect to the direction along the pair of sides, of the input/output portion from a back surface side; and a guide member that is disposed on a back surface side of the front frame so that when the support member is in a storage state, the support member is located on a front surface side, and when the support member is in a drawn out state, the guide member supports a base end side of the input/output portion from the back surface side, wherein the input/output portion is housed wound or bent in the pair of sides direction, in a space between a bottom surface of the casing and the guide member, and is drawn out from or wound back into the space via a gap formed between the guide member and the casing in an end portion of the casing on a side opposite to a drawing out side of the support member.

According to the configuration described above, in a mobile information terminal device such as a wristwatch type information terminal, a game machine, a tablet terminal, or a personal computer, or here in the case of a wristwatch type information terminal for example, a predetermined function can be fulfilled with the size of a normal dial face for displaying the time. However, it is difficult to realize the display and/or input operations sufficiently with only the area of the dial face, as the information terminal device, and heretofore the functions that can be realized were limited. Therefore, according to the present invention, the film-like input/output portion, which has a pair of sides that are parallel to each other and realizes at least some functions of display and/or input operations, is to be used drawn out in the direction of the pair of sides from one side portion of the mobile information terminal.

Specifically, the casing is box shaped so as to be able to house, for example, the rectangular film-like input/output portion that includes the pair of sides that are parallel to each other in an internal space inside the casing, the one side portion of the casing is open, and an opening portion that exposes the input/output portion is formed in the front frame of the front surface of the casing. Also, the support member and the guide member that are stacked on one another are housed in the casing. The support member is able to move into/out from the casing in the direction of the pair of sides of the input/output portion, and is attached to the free end portion side of the input/output portion to support the free end portion side from the back surface side thereof. In doing so, the support member supports the film-like input/output portion so as to be planar and so as to enable touch operations free of hindrance, and the support member and the input/output portion can be drawn out from the casing in one piece. The guide member is disposed on the back surface side of the front frame of the casing so that when the support member is in a storage state, the support member is located on the front surface thereof, that is, the support member is stacked thereon. On the other hand, the guide member supports the base end side of the drawn out film-like input/output portion from the back surface thereof so as to be planar and so as to enable touch operations free of hindrance, in a state where the support portion is drawn out. Also, the input/output portion is housed wound or bent in the pair of sides direction, in a space between a bottom surface of the casing and the guide member, and is drawn out from or wound back into the space via a gap formed between an end portion of the casing on the side opposite to a drawing out side of the support member and the guide member.

Accordingly, the free end portion side is exposed from the opening portion when the input/output portion is in a storage state, and input/output operations can be made with the exposed portion alone, and, as a result of the support member being drawn out, the base end portion side that is drawn out in one piece with the support member is drawn out from the space via the gap and faces the opening portion and is supported from the back surface side thereof by the support member, and thus the entire surface of the input/output portion can be used to perform input and output operations. Thus, the information terminal device is compact, and high-level functionality and/or multifunctionality can be realized by drawing out the input/output portion. Also, even when the film-like input/output portion is drawn out, the free end portion side of the input/output portion is supported (backed) by the support member and the base end portion side is supported (backed) by the support surface of the casing, and thus improvements in the support structure can be realized.

Also, the information terminal device of the present invention further includes an angle adjustment mechanism that is provided at an end portion of the guide member on the drawing out side of the support member and is configured to pivotably support an end portion of the support member on the side opposite to the drawing out side so as to enable angle adjustment.

According to the configuration described above, the drawn out support member and the casing, that is, the portion spanning from the free end portion side to the base end portion side of the film-like input/output portion, do not only extend (are not only connected) on straight lines, but can also be connected at an angle by the angle adjustment mechanism.

Therefore, by creating the angle, in usage as a wristwatch type information terminal device, for example, the free end portion side of the drawn out input/output portion faces upward, and the visibility is improved, or in usage as an information terminal device used as a mobile phone, the free end portion side approaches an ear, and the base end portion side approaches a mouth, and talking is made easier.

Also, in the information terminal device of the present invention, the casing is shaped as a rectangular parallelopiped that is open on one end side, the support member has a substantially L-shaped or U-shaped short-direction cross section formed by folding one or both end portions in a width direction of an elongated plate-shaped body, and the guide member has a substantially L-shaped or U-shaped short-direction cross section formed by folding one or both end portions in a width direction of an elongated plate-shaped body, and is fitted into the support member and fixed to the bottom surface of the casing to enable drawing out of the support member.

According to the configuration described above, the outer side of the support member with an L-shaped or U-shaped cross section is guided from the rear side of the front frame of the casing along the inward side of side walls, and the inward side of the support member is guided along the outer side of the guide member with an L-shaped or U-shaped cross section. Also, the guide member is stored inside the casing, and also shortened by an amount corresponding to the gap.

Accordingly, the input/output portion and the support member can move into/out of the casing, and the space in which the base end side of the input/output portion is housed can be formed.

Also, in the information terminal of the present invention, the guide member is shortened to extend to a position a predetermined length inward of one side portion on the drawing out side of the casing, and each folded portion of the guide member includes a first elongated hole that extends in a drawing out direction of the support member and is open in an end portion in the drawing out direction, in the vicinity of an end portion of each folded portion of the support member on the side opposite to the drawing out side, a first guide pin is provided protruding inward and is fitted into the first elongated hole, and the angle adjustment mechanism includes: an angular displacement member that is provided in the casing in a space on the one side portion side formed by shortening the guide member, is configured to guide the support member, and includes a pin hole that is in communication with the first elongated hole of the guide member and into which the first guide pin is fitted in a state where the support member is drawn out, and a fixed member that is fixed to a bottom plate of the casing and pivotably supports the angular displacement member so as to enable angle adjustment.

According to the configuration described above, in order to angle adjustably support the free end side of the film-like input/output portion and the support member on which the free end side is mounted when drawn out from the one side portions of the casing, first, in the support member and the guide member that each have a U-shaped cross section and are stacked on one another, the folded portions of the guide member are respectively provided with first elongated holes for guiding, and, in correspondence therewith, in the vicinity of the end portions of the bent portions of the support member on the side opposite to the drawing out side, first guide pins are provided protruding inward and are fitted into the first elongated holes, and thus the input/output portion and the support member can be drawn out.

Next, the angle adjustment mechanism is provided in the space on the exit side of the casing formed by shortening the guide member. The angle adjustment mechanism is configured to include an angular displacement member that is continuous with the guide member, and a fixed member that is fitted into the support member and fixed to the bottom surface of the casing to pivotably support the angular displacement member so as to enable angle adjustment. It should be noted that, in order to support and guide the L-shaped or U-shaped support member from the inward side thereof, the angular displacement member includes pin holes that are respectively in communication with the first elongated holes of the guide member, and receive the first guide pins when the support member is drawn out.

Accordingly, as the support member is drawn out, the first guide pins move into the corresponding pin holes of the angular displacement member from the first elongated holes of the guide member, that is, the guide member is transferred from the guide member to the angular displacement member of the angle adjustment mechanism. Thus, it is possible to realize an input/output portion of which the angle is adjustable after being drawn out.

Furthermore, in the information terminal device of the present invention, each folded portion of the support member is provided with a second elongated hole that extends in the drawing out direction of the support member, and a second guide pin that is fitted into the second elongated hole is provided outward of the pin hole of the angular displacement member.

Accordingly, the guide member is guided by the two elongated holes and the two guide pins that the two elongated holes correspondingly receive.

Thus rattling in the slide operations of the support member and the input/output portion can be suppressed

Also, in the information terminal of the present embodiment, the angular displacement member of the angle adjustment mechanism includes a locking member that is located on an entrance side of the pin hole and is configured to retract from the entrance under a pressing force of the first guide pin upon the first guide pin entering the pin hole, and to block off the entrance after the first guide pin has moved into the pin hole.

According to the configuration described above, when the first guide pins are fitted into the pin holes, the locking members act as retainers (prevent retraction), and thus the first guide pins can stably transition from the first elongated holes to the pin holes. The locking members can, for example, be realized by projections that can move into/out of the entrance and spring members that elastically bias the projections in a protruding direction from the rear side thereof

Accordingly, even if the base end side of the input/output portion is pulled by springs or the like and subjected to tension, a situation such as the drawn out input/output portion and the support member being undesirably drawn back can be prevented, and there is no need to separately provide a locking means so as to keep the drawn out input/output portion and the support member from being drawn back.

Furthermore, in the information terminal device of the present invention, the front frame is overall U-shaped and includes a first frame portion that covers the gap on the side opposite to the drawing out side of the support member, and second and third frame portions that respectively cover two side portions of the input/output portion to be drawn out, the second and third frame portions extending to a folding line of the input/output portion formed by the angularly displaced angular displacement member and the fixed member.

According to the configuration described above, the front frame is configured to include a first frame portion that covers the gap of the support member on the opposite side to the drawing out side, and second and third frame portions that respectively cover both side portions of the drawn out input/output portion. In other words, the front frame has an overall U shape with the drawing out side of the support member cut out therefrom. Thus, the input/output portion can be one continuous screen from the free end portion side, which is exposed before the input/output portion is drawn out, to the base end portion side that appears when drawn out.

Furthermore, by forming the overall U-shaped second and third frame portions of the front frame to extend to a folding line of the input/output portion formed by the angularly displaced angular displacement member and the fixed member, even if the drawn out portion is angularly displaced inward, a folding line portion does not rise and the continuous screen can be formed with the folding line portion folded in a smooth curve.

Also, the information terminal device of the present invention is a mobile information terminal device including: an input/output portion that is film-like and includes a pair of sides that are parallel to each other, and realizes display and/or input operations as the information terminal device; a casing that includes, in a front surface thereof, a support surface that supports the input/output portion from a back surface side thereof, and that is configured to internally house a portion of the input/output portion that is wound or bent in a longitudinal direction; and a support member that is configured to move into/out from the casing in a direction along the pair of sides of the input/output portion, and configured to be drawn out from the casing in one piece with the input/output portion by supporting a free end portion side, with respect to the direction of the pair of sides, of the input/output portion from a back surface side, wherein the casing further includes: a guide means that enables the support member to move into/out from the casing by guiding a base end side of the support member on the support surface; and an angle adjustment mechanism configured to support a base end side of the support member so as to enable swinging and angle adjustment of the support member in a state where the support member is drawn out.

According to the configuration described above, in a mobile information terminal device such as a wristwatch type information terminal, a game machine, a tablet terminal, or a personal computer, or here in the case of a wristwatch type information terminal for example, a predetermined function can be fulfilled with the size of a normal dial face for displaying the time. However, it is difficult to realize the display and/or input operations sufficiently with only the area of the dial face, as the information terminal device, and heretofore the functions that can be realized were limited. Therefore, according to the present invention, the film-like input/output portion, which has a pair of sides that are parallel to each other and realizes at least some functions of display and/or input operations, is to be used drawn out in the direction of the pair of sides from one side portions of the mobile information terminal.

Specifically, the casing is box shaped so as to be able to house a portion of, for example, the rectangular film-like input/output portion that includes the pair of sides that are parallel to each other (this portion is referred to as the base end portion side) wound or bent in the longitudinal direction thereof in an internal space inside the casing, and by supporting the remaining portion of the input/output portion that is constantly exposed and continuous from the internal space (this portion is referred to as the free end portion side) by attaching it to the plate shaped support member or the like, and further drawing out the support member from one side portions of the casing, the input/output portion can be exposed continuous from the free end portion side to the base end portion side thereof. At this time, the back surface of the free end portion side of the input/output portion is supported by the support member, and the drawn out base end portion side is supported from the back surface side by a support surface that is the front surface of the casing. Thus, touch operations and the like can be performed on the entire input/output portion without hindrance, and the input/output portion can be drawn out in one piece from the casing.

On the other hand, in order for the plate-shaped support member to move into/out of the casing, by, for example, providing a guide means in which two sides of the support surface of the casing are respectively provided with ridges (edges) that respectively include guide grooves that are parallel with the support surface and making pins that are to be fitted into the guide grooves, respectively, protrude from the base end portion of the support member, and guiding (causing parallel movement between) the base end portion side of the support member on the support surface using the guide means, the support member is able to move into/out of the casing.

Furthermore, in a state where the support member is drawn out, the region spanning from the free end portion side of the input/output portion to the base end portion side extends to be substantially planar, that is, extends in a substantially straight line, and thus the angle adjustment mechanism is provided to improve visibility or facilitate operations. The angle adjustment mechanism swingably and angle adjustably supports the base end portion side of the support member in a state where the support member is drawn out.

Accordingly, the free end portion side is exposed at the front surface when the input/output portion is in a storage state, and input/output operations can be made with the exposed portion alone, and, as a result of the support member being drawn out, the base end portion side that is drawn out in one piece with the support member moves over the support surface and forms a continuous screen with the free end portion side. Thus, an information terminal device can realize high-level functionality and/or multi-functionality with a compact configuration by drawing out the film-like input/output portion. Also, even when the film-like input/output portion is drawn out, the free end portion side of the input/output portion is supported (backed) by the support member and the base end portion side is supported (backed) by the support surface of the casing, and thus improvements in the support structure can be realized.

Furthermore, in the information terminal device of the present invention, the pins are prismatic or plate shaped, and the angle adjustment mechanism is formed by a plurality of slots that are in communication with the corresponding guide grooves and extend at a plurality of angular positions.

According the configuration described above, by making the pins that guide the base end side of the support member prismatic or plate shaped, the pins slide without rotating in the guide grooves, and continue on to be fitted into the slots that are in communication with the guide grooves. Also, by forming the slots so as to extend at a plurality of angular positions, the angle of the free end portion side of the input/output portion can be adjusted by a user fitting the pins into the slots.

Also, in the information terminal device according to the present invention, the display in the input/output portion is realized by an electronic paper.

According to the configuration described above, the electronic paper is thin and flexible. Accordingly, an electronic paper is favorable as the film-like input/output portion that is housed wound or bent in the casing, and forms a continuous screen when drawn out.

Furthermore, in the information terminal device according to the present invention, the display in the input/output portion is realized by an organic FT film display with a resin substrate.

According to the configuration described above, as one example of an organic EL film display, an organic EL film display with a resin substrate is thin and flexible. Accordingly, an organic EL film display is favorable as the film-like input/output portion that is housed wound or bent in the casing, and forms a continuous screen when drawn out.

Furthermore, the information terminal device according to the present invention is a wristwatch type information terminal.

Although a wristwatch type information terminal is small and compact, the amount of display and/or input operation ability is limited by the area of a dial face, but according to the above configuration, by enlarging the area of the input/output portion by drawing out the input/output portion, as appropriate, as in the information terminal device according to the present invention, the functionality as an information terminal device can be improved.

### INDUSTRIAL APPLICABILITY

An information terminal device according to the present invention is configured to be compact by drawing out a film-like input/output portion from a casing when used, and in a wristwatch type information terminal device or a mobile information terminal device such as a game machine, a support member supports a back surface of a free end portion side of the input/output portion, the support member is sandwiched between a guide member and a front frame of a casing, and the guide member enables the support member to move into/out from the casing, and thus input/output operations can be reliably performed on the film-like input/output portion. Therefore, high-level functionality and/or multi-functionality can be realized in an information terminal device, and this configuration is favorable.

1. A mobile information terminal device comprising:
an input and output portion that is film-like, that comprises a pair of sides that are parallel to each other, and through which display operations and input operations of an information terminal device can be performed;
a casing that comprises a front frame in a front surface thereof, wherein the front frame comprises an opening that exposes the input and output portion;
a support member configured to move into and out from the casing in a direction along the pair of sides of the input and output portion, and configured to be drawn out from the casing in one piece with the input and output portion by supporting a free end portion side, with respect to the direction along the pair of sides, of the input and output portion from a back surface side; and
a guide member that is disposed on a back surface side of the front frame so that when the support member is in a storage state, the support member is located on a front surface side, and when the support member is in a drawn out state, the guide member supports a base end side of the input and output portion from the back surface side,
wherein the input and output portion is housed while wound or bent in the direction along the pair of sides, in a space between a bottom surface of the casing and the guide member, and is drawn out from or wound back into the space via a gap formed between the guide member and the casing in an end portion of the casing on a side opposite to a drawing out side of the support member.

2. The information terminal device according to claim 1, further comprising:
an angle adjustment mechanism that is provided at an end portion of the guide member on the drawing out side of the support member and is configured to pivotably support an end portion of the support member on the side opposite to the drawing out side so as to enable angle adjustment.

3. The information terminal device according to claim 2,
wherein the casing is shaped as a rectangular parallelepiped that is open on one end side,
the support member has a substantially L-shaped or U-shaped cross section formed by folding one or both end portions in a width direction of an elongated plate-shaped body, and
the guide member has a substantially L-shaped or U-shaped short-direction cross section formed by folding one or both end portions widthwise of an elongated plate-shaped body, and is fitted into the support member and fixed to the bottom surface of the casing to enable drawing out of the support member.

4. The information terminal device according to claim 3,
wherein the guide member is formed to extend to a position a predetermined length inward of one side portion on the drawing out side of the casing, and each folded portion of the guide member includes a first elongated hole that extends in a drawing out direction of the support member and is open in an end portion in the drawing out direction,
wherein, proximately to an end portion of each folded portion of the support member on the side opposite to the drawing out side, a first guide pin is provided that protrudes inward and that is fitted into the first elongated hole, and
wherein the angle adjustment mechanism comprises:
an angular displacement member that is provided in the casing in a space between the one side portion side and the guide member, is configured to guide the support member, and comprises a pin hole that aligned with the first elongated hole of the guide member and into which the first guide pin is fitted in a state where the support member is drawn out, and
a fixed member that is fixed to a bottom plate of the casing and that pivotably supports the angular displacement member so as to enable angle adjustment.

5. The information terminal device according to claim 4,
wherein each folded portion of the support member comprises a second elongated hole that extends in the drawing out direction of the support member, and
a second guide pin that is fitted into the second elongated hole and that is provided outward of the pin hole of the angular displacement member.

6. The information terminal device according to claim 5,
wherein the angular displacement member of the angle adjustment mechanism comprises a locking member that is located on an entrance side of the pin hole and is configured to retract from the entrance under a pressing force of the first guide pin upon the first guide pin entering the pin hole, and to block off the entrance after the first guide pin has moved into the pin hole.

7. The information terminal device according to claim 6,
wherein the front frame is substantially U-shaped and comprises a first frame portion that covers the gap on the side opposite to the drawing out side of the support member, the front frame further comprising second and third frame portions that respectively cover two side portions of the input and output portion to be drawn out, the second and third frame portions extending to a folding line of the input and output portion formed by the angularly displaced angular displacement member and the fixed member.

8. A mobile information terminal device comprising:
an input and output portion that is film-like and that comprises a pair of sides that are parallel to each other, and through which display operations and input operations of an information terminal device;
a casing that comprises a front surface and further comprises in the front surface a support surface that supports the input and output portion from a back surface side of the input and output portion and that is configured to internally house a portion of the input and output portion that is wound or bent in a longitudinal direction; and
a support member that is configured to move into and out from the casing in a direction along the pair of sides of the input and output portion, and configured to be drawn out from the casing in one piece with the input and output portion by supporting a free end portion side, with respect to the direction along the pair of sides, of the input and output portion from a back surface side,
wherein the casing further comprises:
a guiding means that enables the support member to move into and out from the casing by guiding a base end side of the support member on the support surface; and
an angle adjustment mechanism configured to support a base end side of the support member so as to enable swinging and angle adjustment of the support member in a state where the support member is drawn out.

9. The information terminal device according to claim 8,
wherein the guide means further comprises:
in the casing, a pair of ridges respectively formed on two sides of the support surface, and a pair of guide grooves that are respectively formed in opposing surfaces of the ridges and are parallel with the support surface; and
pins that protrude outward from the pair of sides of the input and output portion on the base end side of the support member and are respectively fitted into the guide grooves.

10. The information terminal device according to claim 9,
wherein the pins are one of prismatic or plate shaped, and the angle adjustment mechanism is formed by a plurality of slots that are aligned with the corresponding guide grooves and extend at a plurality of angular positions.

11. The information terminal device according to claim 10, wherein the input and output portion comprise electronic paper through which the display operations are performed.

12. The information terminal device according to claim 10, wherein the input and output portion comprises an organic EL film display with a resin substrate through which the display operations are performed.

13. The information terminal device according to claim 12, further comprising a wristwatch that comprises the input and output portion, the support member, and the casing.

14. The information terminal device according to claim 13, wherein the watch comprises one or more sensors.

15. The information terminal device according to claim 14, wherein the display operations use information collected by the sensors based on user input.

16. The information terminal device according to claim 1, wherein the input and output portion comprise electronic paper through which the display operations are performed.

17. The information terminal device according to claim 1, wherein the input and output portion comprises an organic EL film display with a resin substrate through which the display operations are performed.

18. The information terminal device according to claim 1, further comprising a wristwatch that comprises the input and output portion, the support member, and the casing.

19. The information terminal device according to claim 18, wherein the watch comprises one or more sensors.

20. The information terminal device according to claim 19, wherein the display operations use information collected by the sensors based on user input.
